(19) United States
(12) Patent Application Publication
(10) Pub. No.: US 2007/0133819 A1
(43) Pub. Date: Jun. 14, 2007

(54) Method for establishing the separation signals relating to sources based on a signal from the mix of those signals

(76) Inventor: Laurent Benaroya, Neuilly (FR)

Correspondence Address: YOUNG & THOMPSON, 745 SOUTH 23RD STREET, 2ND FLOOR, ARLINGTON, VA, 22202, US

(21) Appl. No.: 11/298,659

(22) Filed: Dec. 12, 2005

(51) Int. Cl. H04B 15/00; G06F 15/00; H03F 1/26

(52) U.S. Cl. 381/94.1; 702/190

(57) ABSTRACT

A method for establishing the separation signals relating to audible sources based on a signal from the mix of those signals, the signals being in the form of successive units, the method including a step for establishing an estimate signal for each of the sources. The method further includes, for each of the sources: a step (E40) for predicting a predicted signal for the present unit based on the separation signal for the preceding unit; and a step for establishing the separation signal (E50) for the present unit based on the predicted signal and the estimate signal.

The present invention relates to a method for establishing the separation signals relating to audible sources based on a signal from the mix of those signals.

### BACKGROUND OF THE INVENTION

The field of the present invention is that of digital signal processing relating to audible sources, also more simply referred to as sound signals, audiophonic signals or audio signals. In that particular field, processing operations carried out on the sound signals are not carried out in the time domain, but in the frequency domain. Therefore, a Short Term Fourier Transform (STFT) is often used before any processing operation. STFT is a linear transform which associates a bidimensional time/frequency signal, denoted here as x(tₖ,f), with a signal in the sampled time domain {x(t₁), . . . , x(t_{N})}. Here tₖ is an index of the sampled digital signal and f is a discrete frequency index. The signal x(tₖ,f) is therefore a signal in the frequency domain and it is in the form of units indexed in the form tₖ.

In the present description, all the values referred to are described by means of random Gaussian multidimensional variables. The mix observed at time t is expressed in the form:
S_{obs}(t,f)=S(t,f)+b(t,f)

where b(t) is a white Gaussian noise having variance σ_{b}² and S(t,f) is the vector, each component of which is associated with a source:

$$S ( t , f ) = ( \begin{matrix}\begin{matrix}{s}_{1} ( t , f ) \\ ⋮\end{matrix} \\ {s}_{N} ( t , f )\end{matrix} )$$

For each frequency f and for each source i, s₁(t,f) follows a centered Gaussian law having variance σᵢ²(f)

In order to denote the variables in the form of a vector or matrix, upper-case letters are used.

Furthermore, in the present application, the notion of a signal is often identical to that of the random variable which represents it.

As for the separation of audio signals, a method has already been published in the literature. It is based on a filter, referred to as the Wiener filter, which carries out an estimate of the separation signal Ŝ_{W}(t,f) under the hypothesis of stationarity of the mixed signals. Let x(tₖ,f) be the random variable which describes the mix of the source signals in the frequency domain. If x(tₖ,f) is applied as input of the filter, the expectation of the random variable which describes the output signal of the filter is conditioned x(tₖ,f). It is possible to write:
Ŝ_{W}(tₖ,f)=E[S(t_{k,f})|x(tₖ,f)]

In the case of the wiener Filter, each component of the vector Ŝ_{W}(tₖ,f) can be obtained with:

$${\hat{S}}_{w} ( t , f ) = ( \begin{matrix}\begin{matrix}{\hat{s}}_{W , 1} ( t , f ) \\ ⋮\end{matrix} \\ {\hat{s}}_{W , N} ( t , f )\end{matrix} ) with {\hat{s}}_{W , i} ( t , f ) = \frac{{e}_{i} ( f )}{{\sum }_{j = 1 … N}^{} {e}_{j} ( f ) + {σ}_{b}^{2}} x ( t , f )$$

where eᵢ(f) is the fraction of energy from the source i a prior contained in the mixed signal, at the index frequency f, N being the total number of sources and x(tₖ,f) being the mixed signal.

Purely by way of illustration, consideration is given to the particular case involving two sources which supply signals which are denoted, in the time domain, s₁(t) and s₂(t). At the start, there is provided a sound signal which is denoted in the time domain x(t) and which is representative of the mix of those sound signals:
x(t)=s₁(t)+s₂(t).

In a prior learning phase, the two audible sources have been evaluated, and the respective characteristic spectral forms thereof σ₁²(f) and σ₂²(f) have been estimated more precisely and represent, definitively as is known, the energy distributions thereof as a function of frequency. If it is considered that the signals in the frequency domain relating to those two sources s₁(t,f) and s₂(t,f) are random Gaussian variables, which are not stationary, σ₁²(f) and σ₂²(f) represent the variance thereof, respectively. The Wiener filter supplies an estimate of the sound signal of each source and, this being in the frequency domain, in accordance with the following relationships:

$${\hat{s}}_{W , 1} ( t , f ) = \frac{{σ}_{1}^{2} ( f )}{{σ}_{1}^{2} ( f ) + {σ}_{2}^{2} ( f )} x ( t , f )$$

$${s}_{W , 2} ( t , f ) = \frac{{σ}_{2}^{2} ( f )}{{σ}_{1}^{2} ( f ) + {σ}_{2}^{2} ( f )} x ( t , f )$$

which can be written in matrix form as follows:
S(tₖ,f)=P·x(tₖ,f)

where P is a matrix which describes the weighting coefficients and which is given below for N sources:

$$P = [ \frac{{σ}_{1}^{2} ( f )}{{\sum }_{i = 1}^{N} {σ}_{1}^{2} ( f )} , … , \frac{{σ}_{N}^{2} ( f )}{{\sum }_{i = 1}^{N} {σ}_{1}^{2} ( f )} ]$$

In the context of separating sound signals, the Wiener filter has the following main disadvantages. It operates in an identical manner relative to all the units of the mixed sound signal and therefore it does not retain changes in the audible energy content from one unit to the next. In definitive terms, it is not an adaptive filter. Another disadvantage consists in that it takes into consideration only one characteristic spectral form per audible source, even if the audible sources have a great spectral variety in terms of timbre, pitch, intensity, etc.

Improvements to the Wiener filter have been proposed in order to take account of those disadvantages and have led in particular to two methods which are substantially based on the use of multiple spectral forms in order to describe each of the sources involved.

The first of those methods has been introduced in the context of voice recognition and has subsequently been used in audio fields. According to that method, the sound signal from each source sᵢ(t) is characterized by a set of Kᵢ spectral forms σₖ_{ᵢ}²(f), kᵢ ε [1, . . . , Kᵢ]. If N sources are considered, their mix is characterized by a set of K₁×K₂× . . . ×K_{N} N-tuplets of characteristic spectral forms (σₖ_{₁}²(f), . . . , σₖ_{_{N}}²(f)). For each index unit tₖ, the method first comprises selecting the N-tuplet of spectral forms which best corresponds to the sound signal of the mix. For example, it may consist in maximizing the probability of correspondence between the spectrogram of the mix |x(tₖ,f)|² and the variance resulting from the pair of spectral forms. Next, it consists in filtering, through a conventional Wiener filter, the mix using the N-tuplet of spectral forms selected in this manner. It is possible to establish that this method is adaptive because the selection of the parameters of the filter depends on the unit index tₖ considered.

The main disadvantage of that method concerns the algorithmic complexity thereof. If K characteristic spectral forms per source i and N sources i are considered in the mix, K^{N} N-tuplets of characteristic spectral forms must be tested for each unit so that the complexity is in the order of O(Kⁿ×T) if T is the number of units of the mixed signal to be analyzed. That disadvantage in terms of complexity can make that method incompatible, in particular when the number of characteristic spectral forms per source is relatively large.

Another method has also been proposed in order to make the separation method adaptive. As above, the sound signal of each source sᵢ(t) is characterized by a set of Kᵢ characteristic spectral forms σₖ_{ᵢ}²(f), but which in that case are combined into a dictionary of spectral forms. In this manner, the spectrogram of the mix |x(tₖ,f)|² is decomposed over the combination of the dictionaries present and it is therefore possible to write:

$$\vert {x ( {t}_{k} , f \vert}^{2} \approx {\sum }_{{k}_{1} = 1}^{{K}_{1}} {a}_{{k}_{1}} ( {t}_{k} ) {σ}_{{k}_{1}}^{2} ( f ) + … + {\sum }_{{k}_{2} = 1}^{{K}_{N}} {a}_{{k}_{N}} ( {t}_{k} ) {σ}_{{k}_{N}}^{2} ( f )$$

where the coefficients aₖ_{ᵢ}(t), which are referred to as “amplitude factors”, are the unknown values to be resolved.

It should be noted that the above equation can be interpreted as if there were K₁+ . . . +K_{N} stationary elemental sources which are each characterized by a spectral form σₖ_{ᵢ}²(f) and which are mixed with each other with respective amplitude factors aₖ_{ᵢ}(t) as a function of time. It should be noted that each amplitude factor aₖ_{ᵢ}(t) of an elemental source is characteristic of the envelope of that source. Therefore, it is a positive number.

The above equation can be re-written as follows:

$${\vert x ( {t}_{k} , f ) \vert}^{2} \approx {\sum }_{i = 1}^{N} {e}_{i} ( {t}_{k} , f ) with {e}_{i} ( {t}_{k} f ) = {\sum }_{k = 1}^{{K}_{i}} {a}_{k} ( {t}_{k} ) {σ}_{k , i}^{2} ( f )$$

eᵢ(tₖ,f) represents the fraction of energy from the source i that is contained in the mix to be analyzed.

A first method for estimating the sound signals from the sources 1 to N is to carry out conventional frequency/time Wiener filtering, which is nevertheless adaptive since it depends on the unit index t. That filter is referred to as a generalized Wiener filter. Therefore, there is, for the source i, the estimate ŝ_{i,w}_{_{g}}(tₖ,f):

$${\hat{s}}_{i , {W}_{g}} ( {t}_{k} , f ) = \frac{{e}_{i} ( {t}_{k} , f )}{{\sum }_{i = 1}^{N} {e}_{i} ( {t}_{k} , f )} x ( {t}_{k} , f )$$

Another method, referred to as a resynthesis method, considers the amplitude of the sound signal of each source i to be equal to \sqrt{eᵢ(tₖ,f)} and its phase to be estimated by that of the mix. Therefore, it is possible to write for the source i:
\tilde{s}ᵢ(tₖ,f)=\sqrt{eᵢ(tₖ,f)}·sign[\tilde{x}(tₖ,f)]

where sign

$$[ x ] = \frac{x}{\vert x \vert}$$

corresponds to the phase of x.

That second method using a dictionary of characteristic spectral forms has the advantage over the previous method of reducing the algorithmic complexity. For n sources each having K spectral forms, the algorithmic complexity is in the order of O(n×K×T), where T is the number of units to be analyzed and is therefore less than that of the previous method which was in the order of O(Kⁿ×T).

The three methods which have been set out above nevertheless have the major disadvantage that the phase of each of the sources involved (or the elemental sources involved depending on the method used) is strictly equal to the phase of the mix. In general, the sources which are added together do not all have the same phase so that, in the methods set out above, during the separation operation, the phase structure of the sources is destroyed, which may lead to disruptive effects when listening to the sound signals of the recovered sources. For the human auditory system is very sensitive to phase coherences in audio signals, in particular inter-unit coherences for fixed f (coherent phase between s(tₖ₊₁,f) and s(tₖ,f)) and the phase coherences for the same unit but for different values of the frequency f(s(tₖ,f) phase for different values of f). Those coherence phase effects are very sensitive in particular to harmonic sounds, such as the sounds from a musical instrument, or voiced sounds, whereas they are less important with respect to white noise, pink noise, etc., or the sounds from percussion instruments.

The object of the present invention is to provide a method for separating the signals relating to audible sources based on a signal from a mix of those signals which does not have the phase incoherences of the methods set out above.

### SUMMARY OF THE INVENTION

To that end, the invention relates to a method for establishing the separation signals relating to audible sources based on a signal from the mix of those signals, the signals being in the form of successive units, the method including a step for establishing an estimate signal for each of the sources. It is characterized in that it further includes, for each of the sources:

a step (E40) for predicting a predicted signal for the present unit based on the separation signal for the preceding unit,

a step (E50) for establishing the separation signal for the present unit on the basis of the predicted signal and the estimate signal.

This method is also used for non-audible signals, such as all digital signals resulting from the sampling of a transducer allowing the transformation of a physical value into an electrical signal.

To that end, the invention relates to a method for establishing the separation signals relating to non-audible sources based on a signal from the mix of those signals, the signals being in the form of successive units, the method including a step for establishing an estimate signal for each of the sources, characterized in that it further includes, for each of those sources:

a step for predicting a predicted signal for the present unit based on the separation signal for the preceding unit,

a step for establishing the separation signal for the present unit based on the predicted signal and the estimate signal.

Advantageously, the step for establishing the separation signal comprises adding together in a weighted manner the estimate signal and the predicted signal, the weighting coefficients being established so as to minimize the covariance of the separation signal.

Advantageously, the estimate signal is weighted by a first matrix coefficient whereas the predicted signal is weighted by a second matrix coefficient which is equal to the unit matrix minus the first matrix coefficient, that first matrix coefficient being established so as to minimize the covariance of the separation signal.

The features of the invention mentioned above as well as others will be appreciated more clearly from a reading of the following description of one embodiment, the description being done with reference to the appended drawings, in which:

### BRIEF DESCRIPTION OF THE DRAWINGS

FIG. 1 is a block diagram of a system for separating the signals relating to audible sources based on a signal from a mix of those signals according to the present invention and

FIG. 2 is a chart showing the various steps carried out by a method for separating signals in accordance with the present invention.

### DETAILED DESCRIPTION OF THE PREFERRED EMBODIMENT

In the remainder of the description, there will be considered audible sources which are in themselves elemental, that is to say, which are each characterized by a given characteristic spectral form. However, there will also be considered audible sources whose spectral form characteristic is one characteristic among a plurality of possible spectral form characteristics, for example, belonging to a dictionary of characteristic spectral forms (see the preamble of the present description). As was set out in the preamble of the description, it is therefore possible to consider an audible source to be a weighted combination of a plurality of elemental audible sources, each of which has a given spectral form characteristic (for example, one taken from a dictionary or established).

In order to resolve the problem involving the phase incoherences of the methods of the prior art set out in the preamble of the description, the present invention provides linking means between adjacent units. In other words, each elemental audible source is established in a recursive and iterative manner.

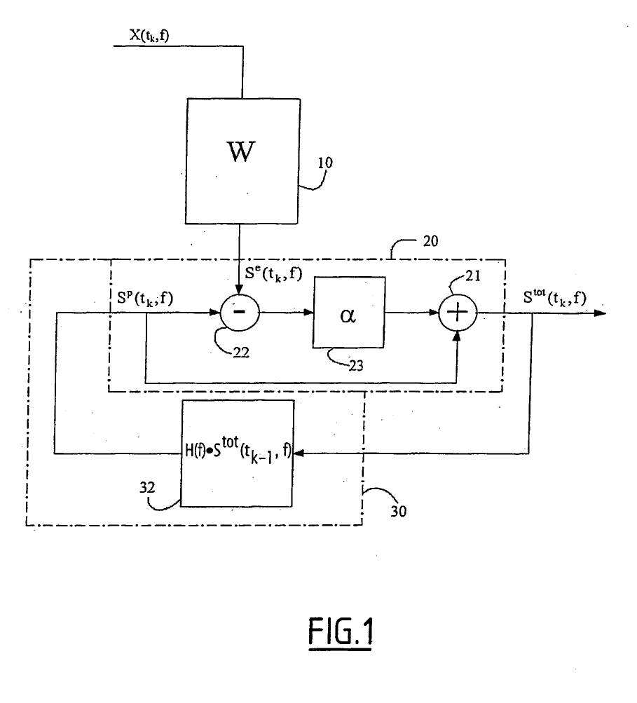

FIG. 1 illustrates a system for separating sound signals from sound sources in accordance with one embodiment of the present invention, which comprises those linking means between adjacent units. That system is substantially constituted by an estimation unit 10 which, on the basis of a mixed signal from the frequency domain denoted x(tₖ,f) obtained, for example, by a short-term Fourier transform of the signal x(t) in the sampled time domain, supplies an estimate signal represented by the random variable S^{e}(tₖ,f), each component of which sᵢ^{e}(tₖ,f) is the estimate signal for a source i of the index mix. If there are N elemental sources, the estimate signal is represented by a vector, each component of which relates to a source:

$${S}^{e} ( {t}_{k} , f ) = ( \begin{matrix}{s}_{1}^{e} ( {t}_{k} , f ) \\ {s}_{N}^{e} ( {t}_{k} , f )\end{matrix} )$$

The estimation unit 10 is such that the expectation of the signal at its output is conditioned with respect to the signals x(tₖ,f) which are actually observed. Therefore, it is possible to write:
S^{e}(tₖ,f)=E[S(tₖ,f)|x(tₖ,f)]
The estimation unit 10 is, for example, a Wiener filter (see the various forms of this type of filter set out in the preamble of the present description), a unit operating by means of a time/frequency threshold method, or using a so-called Ephraïm and Malah method, etc. For example, in the case of a Wiener filter, each component of the vector S^{e}(tₖ,f) can be obtained by the following relationship:

$${S}^{e} ( {t}_{k} , f ) = ( \begin{matrix}\begin{matrix}{\hat{s}}_{1 , {W}_{e}} ( {t}_{k} , f ) \\ ⋮\end{matrix} \\ {\hat{s}}_{N , {W}_{e}} ( {t}_{k} , f ) \end{matrix} ) with {\hat{s}}_{i , {W}_{g}} ( {t}_{k} , f ) = \frac{{e}_{i} ( {t}_{k} , f )}{{\sum }_{i = 1}^{N} {e}_{i} ( {t}_{k} , f )} x ( {t}_{k} , f )$$

where eᵢ(tₖ,f) is the fraction of energy from the source i that is contained in the mixed signal, in the index unit tₖ and index frequency f, N being the total number of sources and \tilde{x}(tₖ,f) being-the mixed signal.

It should be remembered at this point that, for an elemental source i, it is possible to write:

$${e}_{i} ( {t}_{k} , f ) = {\sum }_{{k}_{i} = 1}^{{K}_{i}} {a}_{{k}_{i}} ( {t}_{k} ) {σ}_{{k}_{i}}^{2} ( f )$$

where Kᵢ represents the number of elemental sources being considered for the source i, aₖ_{ᵢ}(tₖ) represents the amplitude factor of the elemental index source kᵢ and σₖ_{ᵢ}² (f) the variance of that elemental index source kᵢ.

The system for separating sound signals of sound sources illustrated in FIG. 1 further comprises an updating unit 20 and a prediction unit 30. Those units 20 and 30 constitute the above-mentioned inter-unit linking means.

The prediction unit 30 is provided in order to supply a prediction signal which is considered to be a corresponding random variable S^{p}(tₖ,f).

It should be remembered at this point that, if there are N elemental sources, the prediction signal is a vector, each component of which relates to a source:

$${S}^{p} ( {t}_{k} , f ) = ( \begin{matrix}{s}_{1}^{p} ( {t}_{k} , f ) \\ ⋮ \\ {s}_{N}^{p} ( {t}_{k} , f )\end{matrix} )$$

As can be seen from FIG. 1, the updating unit 20, on the basis of the prediction signal S^{p}(tₖ,f) supplied by the prediction unit 30 and the estimate signal S^{e}(tₖ,f) supplied by the estimating unit 10, itself supplies the separation signal, whose random variable is denoted S^{tot}(tₖ,f).

If there are N elemental sources, the separation signal is represented by a vector, each component of which relates to a source:

$${S}^{tot} ( {t}_{k} , f ) = ( \begin{matrix}{s}_{1}^{tot} ( {t}_{k} , f ) \\ ⋮ \\ {s}_{N}^{tot} ( {t}_{k} , f )\end{matrix} )$$

With regard to the prediction unit 30, in the simplest case it may involve introducing a desynchronization term between two successive units, by means of its unit 32, and it is therefore possible to write:
S^{p}(tₖ,f)=H(f)·S^{tot}(tₖ₋₁,f)

The predicted signal for the present unit is based on the separation signal for the preceding unit.

The expectation of the prediction signal is given by the following relationship:
Ŝ^{p}(tₖ,f)=H(f)·\tilde{S}^{tot}(tₖ₋₁,f)

where H(f) is a term which, in the frequency domain, is representative of the desynchronization between two successive units and which, owing to the signals considered being stationary signals, can be written:

$$H ( f ) = exp [ 2 πⅈ \frac{fM}{T} ]$$

where T is the length of a unit, M is the desynchronization considered and i is the complex number, so that i²=−1. Generally, the desynchronization M between units is less than the length T of a unit, and it is often even half of the length of a unit:
M=T/2

As for the updating unit 20, it is provided in order to establish the separation signal S^{tot}(tₖ,f) by adding together in a weighted manner the estimate signal S^{e}(tₖ,f) and the predicted signal S^{p}(tₖ,f). In the embodiment illustrated, the estimate signal S^{e}(tₖ,f) is weighted by a matrix coefficient α(tₖ,f) and the predicted signal is weighted by a coefficient I-α(tk,f). I being the unit matrix.

For example, this is carried out by adding, in an adder 21, to the predicted signal S^{p}(tₖ,f), an error signal which is calculated to be the difference between the predicted signal S^{p}(tₖ,f) and the estimate signal S^{e}(tₖ,f), the error signal being weighted by a coefficient α(tₖ,f), the weighting being carried out by a weighting unit 23. Therefore, it is possible to write the relationship:
S^{tot}(tₖ,f)=S^{p}(tₖ,f)+α(tₖ,f)·(S^{e}(tₖ,f)−S^{p}(tₖ,f))

The separation system illustrated in FIG. 1 is provided in order to establish the optimum matrix of coefficients α(tk,f) allowing the variance of the estimate of the separation signal S^{tot}(tₖ,f) to be minimized. It is possible to demonstrate that this optimum value for the weighting factor is given by the following relationship of the covariance of the predicted signal Cov^{p}(tₖ,f) and the sum of the covariance of the predicted signal Cov^{p}(tₖ,f) and the covariance of the estimate signal Cov^{e}(tₖ,f), that is to say:
α(tₖ,f)=[Cov^{e}(tₖ,f)+Cov^{p}(tₖ,f)]⁻¹·Cov^{p}(tₖ,f)

Since the value of the weighting coefficient α(tₖ,f) is known, it is possible to establish the expectation of the separation signal S₀^{tot}(tₖ,f) which therefore constitutes the output from the updating unit 20:
S₀^{tot}(tₖ,f)=S₀^{p}(tₖ,f)+α(tₖ,f)·(S₀^{e}(tₖ,f)−S₀^{p}(tₖ,f))

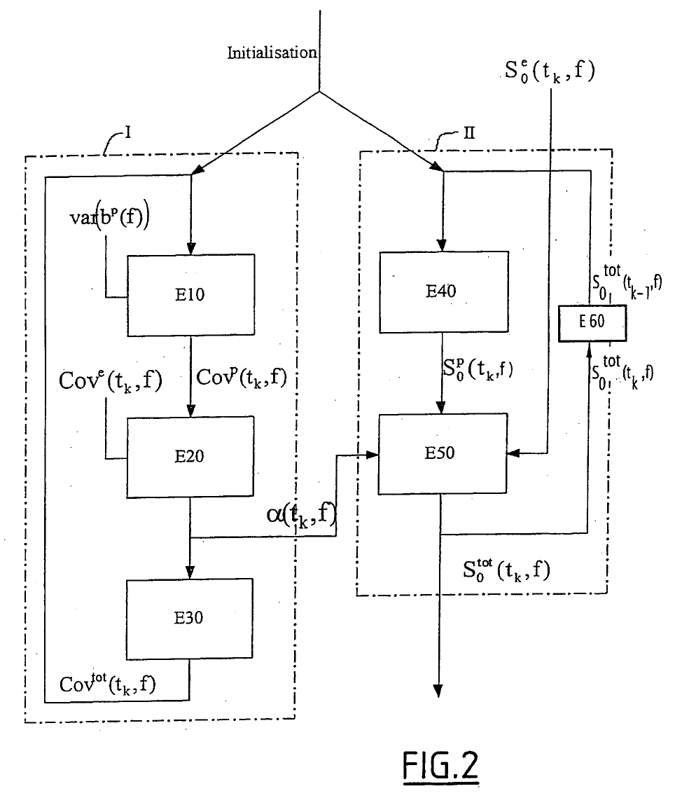

Therefore, the method will be carried out in accordance with the chart of FIG. 2. In that chart, it is evident that there are two branches I and II: the first I includes the steps E10, E20 and E30 and corresponds to the calculations of the covariances of the various random variables substantially leading to the calculation of the optimum matrix of coefficients α(tₖ,f), and the second II which includes the steps E40 and E50 corresponds to the calculations of the expectations of those random variables leading to the calculation of the expectation of the separation signal as a function of the estimate signal supplied by the estimation unit 10.

In greater detail, the updating of the covariance of the predicted signal, which is represented, as will be recalled, by the random variable S^{p}(tₖ₊₁,f), is carried out in step E10.

Owing to the unit 32 which links two successive units to each other, it is readily possible to demonstrate that the covariance of the predicted signal is given by the following relationship:
Cov^{p}(tₖ,f)=Cov^{tot}(tₖ₋₁,f)+var(b^{p}(tₖ,f)) with var(b^{p}(tₖ,f)),
variance of the prediction noise.

The modulus of the function H(f) is equal to 1.

The variance of the prediction noise var(b^{p}(tₖ,f)) depends on the sources or the sub-sources considered and the frequency f. It does not depend on the unit considered, so that it can also be written:
var(b^{p}(tₖ,f))=var(b^{p}(f))

That variance is advantageously estimated in a learning phase. In definitive terms, that is written:
Cov^{p}(tₖ,f)=Cov^{tot}(tₖ₋₁,f)+var(b^{p}(f))

Cov^{tot (t}ₖ₋₁,f) is a value which has been calculated during the preceding iteration (see step E30 below).

In step E20, the optimum matrix of coefficients α(tₖ,f) is established. In order to do that, the expression below is used:
α(tₖ,f)=[Cov^{e}(tₖ,f)+Cov^{p}(tₖ,f)]⁻¹·Cov^{p}(tₖ,f)

The covariance of the separation signal predicted Cov^{p}(tₖ,f) is given by the calculation carried out in step E10. The covariance of the estimate signal Cov^{e}(tₖ,f), is established by the characteristic spectral forms σₖ_{ᵢ}²(f) and the amplitude factors aₖ_{ᵢ}(tₖ) of the sources or elemental sources considered.

It should be remembered that the equation of the mix is as follows:

$$x ( t , f ) = {\sum }_{i} {s}_{i} ( t , f ) + b ( t , f )$$

where b(t,f)represents the expression of a stationary Gaussian white noise having variance σ_{b}². The elemental sources sᵢ(t,f) are a prior considered to be non-stationary Gaussian sources having variance aᵢ(t,f)σᵢ²(f), but to be stationary conditionally upon aᵢ(t).

The estimate signal S^{e}(t,f) of the mix of all the elemental sources is a random Gaussian variable having variance Cov^{e}(t,f).

It has been possible to demonstrate that this covariance of the estimate signal Cov^{e}(tₖ,f) could be expressed as follows:

$${Cov}^{e} ( {t}_{k} , f ) = ( \begin{matrix}{a}_{1} ( {t}_{k} ) {σ}_{1}^{2} ( f ) & 0 & 0 \\ 0 & ⋰ & 0 \\ 0 & 0 & {a}_{N} ( {t}_{k} ) {σ}_{N}^{2} ( f )\end{matrix} ) - \frac{1}{{\sum }_{j = 1}^{N} {a}_{j} ( {t}_{k} ) {σ}_{j}^{2} ( f ) + {σ}_{b}^{2}} ( \begin{matrix}{a}_{1} ( {t}_{k} ) {σ}_{1}^{2} ( f ) \\ ⋮ \\ {a}_{N} ( {t}_{k} ) {σ}_{N}^{2} ( f )\end{matrix} ) ( \begin{matrix}{a}_{1 } ( {t}_{k} ) {σ}_{1}^{2} ( f ) & ⋯ & {a}_{N} ( {t}_{k} ) {σ}_{N}^{2} ( f )\end{matrix} )$$

in which expression:

aⱼ(tₖ,f) is the amplitude factor of the index source or elemental source j for the index unit tₖ and for the index frequency f,

σⱼ(f) is the characteristic spectral form of the index source or elemental source j and for the frequency f,

σ_{b} is the variance of a Gaussian white noise and

N is the total number of elemental sources being considered.

In step E30, the covariance matrix of the separation signal is updated using the following expression:
Cov^{tot}(tₖ,f)=[I−α(tₖ,f)]Cov^{p}(tₖ,f)

in which expression:

I is the identity matrix,

α(tₖ,f) is the matrix of coefficients as established in step E20 above,

Cov^{p}(tₖ,f) is the covariance of the predicted separation signal as calculated in step E10.

After step E30, as regards the calculations linked to the covariances, the following unit is considered and the operation is repeated at step E10.

Consideration is now given to steps E40 and E50 which are linked to the calculations of the expectations. In step E40, the expectation of the predicted signal S₀^{p}(tₖ,f) is established, which is given by the following relationship as a function of the expectation of the separation signal S₀^{tot}(tₖ₋₁,f) which has been established in the preceding unit:
S₀^{p}(tₖ,f)=H(f)·S₀^{tot}(tₖ₋₁f)

In step E50, the expectation of the separation signal is calculated by means of the following expression:
S₀^{tot}(tₖ,f)=S₀^{p}(tₖ,f)+α(tₖ,f)·(S₀^{e}(tₖ,f)−S₀^{p}(tₖ,f))

in which expression:

S₀^{p}(tₖ,f) is the expectation of the predicted separation signal established in step E10 above,

S₀^{e}(tₖ,f) is the expectation of the estimate signal as it appeared at the output from the estimation unit 10 and

α(tₖ,f) is the matrix of coefficients as established in step E20 above.

The expectation of the separation signal S₀^{tot}(tₖ,f) is the output signal of the system. Its components are the separation signals of each of the sources or elemental sources considered.

In step E60, the expectation of the separation signal of the unit Tr, S_{O}^{tot} (tₖ,f)is desynchronized by one unit in order to obtain the expectation of the separation signal of the unit tₖ₋₁ and that last expectation value is used during the step E40.

After the steps E50 and E60, the following unit is considered and the operation is repeated at step E40 with regard to the steps linked to the calculations of the expectations.

The steps E10 and E40 are carried out by the prediction unit 30 and the steps E20, E30 and E50 are carried out by the updating unit 20.

It should be noted that, when the method is initialized, the expectation and the covariance of the random variable representing the separation signal are reset to zero, then the steps E10 and E40 are carried out.

1. Method for establishing the separation signals relating to audible sources based on a signal from the mix of those signals, the signals being in the form of successive units, the method including a step for establishing an estimate signal for each of those sources, characterized in that it further includes, for each of those sources:
a step (E40) for predicting a predicted signal for the present unit based on the separation signal for the preceding unit,
a step (E50) for establishing the separation signal for the present unit based on the predicted signal and the estimate signal.

2. Method for establishing the separation signals relating to non-audible sources based on a signal from the mix of those signals, the signals being in the form of successive units, the method including a step for establishing an estimate signal for each of the sources, characterized in that it further includes, for each of the sources:
a step (E40) for predicting a predicted signal for the present unit based on the separation signal for the preceding unit,
a step (E50) for establishing the separation signal for the present unit based on the predicted signal and the estimate signal.

3. Separation method according to claim 1, characterized in that the step for establishing the separation signal comprises adding together, in a weighted manner, the estimate signal and the predicted signal, the weighting coefficients being established so as to minimize the covariance of the separation signal.

4. Separation method according to claim 3, characterized in that the estimate signal is weighted by a first matrix coefficient and the predicted signal is weighted by a second matrix coefficient equal to the unit matrix minus the first matrix coefficient, that first matrix coefficient being established so as to minimize the covariance of the separation signal.

5. Separation method according to claim 4, characterized in that the value of the first matrix coefficient is calculated by means of the following relationship for the covariance of the predicted signal Cov^{p}(tₖ,f) and the sum of the covariance of the predicted signal Cov^{p}(tₖ,f) and the covariance of the estimate signal Cov^{e}(tₖ,f), that is to say:
α(tₖ,f)=[Cov^{e}(tₖ,f)+Cov^{p}(tₖ,f)]⁻¹·Cov^{p}(tₖ,f).

6. Separation method according to claim 5, characterized in that the covariance of the predicted signal Cov^{p}(tₖ,f) is established as a function of the covariance of the separation signal Cov^{tot}(tₖ₋₁,f) for the preceding unit by means of the following relationship:
Cov^{p}(tₖ,f)=Cov^{tot}(tₖ₋₁,f)+var(b^{p}(f))
var(b^{p}(tₖ,f)) being the variance of the prediction noise which depends on the sources or sub-sources considered.

7. Separation method according to claim 6, characterized in that the variance of the prediction noise var(b^{p}(tₖ,f)) is estimated in a learning phase.

8. Separation method according to claim 5, characterized in that the covariance of the estimate signal Cov^{e}(tₖ,f) is established by means of the following relationship:
$${Cov}^{e} ( {t}_{k} , f ) = ( \begin{matrix}{a}_{1} ( {t}_{k} ) {σ}_{1}^{2} ( f ) & 0 & 0 \\ 0 & ⋰ & 0 \\ 0 & 0 & {a}_{N} ( {t}_{k} ) {σ}_{N}^{2} ( f )\end{matrix} ) - \frac{1}{{\sum }_{j = 1}^{N} {a}_{j} ( {t}_{k} ) {σ}_{j}^{2} ( f ) + {σ}_{b}^{2}} ( \begin{matrix}{a}_{1} ( {t}_{k} ) {σ}_{1}^{2} ( f ) \\ ⋮ \\ {a}_{N} ( {t}_{k} ) {σ}_{N}^{2} ( f )\end{matrix} ) ( \begin{matrix}{a}_{1 } ( {t}_{k} ) {σ}_{1}^{2} ( f ) & ⋯ & {a}_{N} ( {t}_{k} ) {σ}_{N}^{2} ( f )\end{matrix} )$$
in which expression:
aⱼ(tₖ,f) is the amplitude factor of the index source or elemental source j for the index unit tₖ and for the index frequency f,
σⱼ(f) is the characteristic spectral form of the index source or elemental source j and for the frequency f,
σ_{b} is the variance of a Gaussian white noise and
N is the total number of sources or elemental sources considered.

9. Separation method according to claim 5, characterized in that the covariance matrix of the separation signal is updated using the following expression:
Cov^{tot}(tₖ,f)=[I−α(tₖ,f)]Cov^{p}(tₖ,f)
in which expression:
I is the identity matrix;
α(tₖ,f) is the matrix of the first weighting coefficient and
Cov^{p}(tₖ,f) is the covariance of the predicted signal.

10. Separation method according to claim 1, characterized in that it comprises a step for establishing the estimate signal S^{e}(tₖ,f), each component ŝᵢ^{e}(tₖ,f) which corresponds to the estimate of an elemental source i of the estimate signal S^{e}(tₖ,f)being obtained from the following formulae:
$$\begin{matrix}{\hat{s}}_{i}^{e} ( {t}_{k} , f ) = \frac{{e}_{i} ( {t}_{k} , f )}{{\sum }_{j = 1}^{N} {e}_{j} ( {t}_{k} , f )} \cdot x ( {t}_{k} , f ) \\ {e}_{i} ( {t}_{k} , f ) = {\sum }_{{k}_{i} = 1}^{{K}_{i}} {a}_{{k}_{i}} ( {t}_{k} ) {σ}_{{k}_{i}}^{2} ( f )\end{matrix}$$
in which:
eᵢ(tₖ,f) being the fraction of energy of the source i that is contained in the signal from the mix of the signals, in an index unit tₖ and index frequency f, N being the total number of sources;
x(tₖ,f) being the signal from the mix of the signals;
Kᵢ being the number of elemental sources considered for the source i;
aₖ_{ᵢ}(tₖ) being the amplitude factor of the index elemental source kᵢ; and
σₖ_{ᵢ}²(f) being the variance of that index elemental source ki.

11. Separation method according to claim 2, characterized in that the step for establishing the separation signal comprises adding together, in a weighted manner, the estimate signal and the predicted signal, the weighting coefficients being established so as to minimize the covariance of the separation signal.

12. Separation method according to claim 2, characterized in that it comprises a step for establishing the estimate signal S^{e}(tₖ,f), each component ŝᵢ^{e}(tₖ,f) which corresponds to the estimate of an elemental source i of the estimate signal S^{e}(tₖ,f) being obtained from the following formulae:
$$\begin{matrix}{\hat{s}}_{i}^{e} ( {t}_{k} , f ) = \frac{{e}_{i} ( {t}_{k} , f )}{{\sum }_{j = 1}^{N} {e}_{j} ( {t}_{k} , f )} \cdot x ( {t}_{k} , f ) \\ {e}_{i} ( {t}_{k} , f ) = {\sum }_{{k}_{i} = 1}^{{K}_{i}} {a}_{{k}_{i}} ( {t}_{k} ) {σ}_{{k}_{i}}^{2} ( f )\end{matrix}$$
in which:
eᵢ(tₖ,f) being the fraction of energy of the source i that is contained in the signal from the mix of the signals, in an index unit tₖ and index frequency f, N being the total number of sources;
x(tₖ,f) being the signal from the mix of the signals;
Kᵢ being the number of elemental sources considered for the source i;
aₖ_{ᵢ}(tₖ) being the amplitude factor of the index elemental source kᵢ; and
σₖ_{ᵢ}²(f) being the variance of that index elemental source ki.
